(19) United States
(12) Patent Application Publication
(10) Pub. No.: US 2019/0286407 A1
(43) Pub. Date: Sep. 19, 2019

(54) INFOTAINMENT SYSTEM INCLUDING AUDIO SAFETY SOUND AND SAFETY TELLTALE CONFIRMATION

(71) Applicant: Visteon Global Technologies, Inc., Van Buren Township, MI (US)

(72) Inventors: Francis Lehomme, Cergy (FR); Julien Fouques, Cergy (FR); Sophie Chané, Seine (FR); Stéphane Voillot, Courdimanche (FR); Christian Noel, Cergy (FR); Christophe Kerveillant, Cergy (FR); Laurent Ribes, Livilliers (FR); Mikael Capp, Changé (FR)

(21) Appl. No.: 15/922,419

(22) Filed: Mar. 15, 2018

(51) Int. Cl. G06F 3/16; H04N 21/2368; H03G 3/30

(52) U.S. Cl. CPC G06F 3/165; B60W 2050/143; H03G 3/3005; H04N 21/2368

(57) ABSTRACT

Audio and video systems for checking safety sounds and telltales are provided. The audio system includes a digital signal processor with a plurality of safety sounds and a plurality of signatures corresponding thereto. A head unit controller includes a signature and volume checker to identify an expected signature of the one of the safety sounds. The digital signal processor outputs a mixed audio stream and includes a lower bit inserter to replace lower bits of the mixed audio stream with replacement lower bits based on the signature and output a modified audio stream. A lower bit extractor separates and outputs the replacement lower bits and a remainder of the modified audio stream. An audio amplifier unit receives and outputs the remainder of the modified audio stream. The head unit controller rebuilds the signature, determines whether the signature matches the expected signature, and sends an acknowledgment accordingly.

### BACKGROUND

Audio and video systems are commonly found on vehicles and are increasingly utilized to present images, video, and/or audio for infotainment and instrumentation purposes. These systems can include display assemblies for human machine interface (HMI) devices including instrument clusters, heads-up displays (HUDs), and central information displays (CIDs) and are typically connected to a single head unit. These display assemblies may display safety-related information or telltales in the form of icons drawn on display panels of the display assemblies in the vehicle. Similarly, safety sounds may occasionally be played by the audio system in the vehicle to warn the driver and/or passenger about a potential danger (e.g., lane departure, obstacle awareness, too close to an obstacle or another car).

Safety requirements exist to ensure that safety-related information is properly conveyed to the vehicle operator and/or passengers. One such safety requirement is ISO 26262 which provides for functional safety of electrical and/or electronic systems in vehicles and includes a risk classification scheme known as the Automotive Safety Integrity Level (ASIL). Four ASILs currently exist, ASIL A, ASIL B, ASIL C, and ASIL D, with ASIL D representing the highest safety requirements. Thus, it can be necessary to confirm or check that the correct telltale is displayed at the right time and place on the appropriate display assembly. Likewise, it can be advantageous to ensure that any safety related sounds are correctly reproduced for the driver and/or passenger of the vehicle and can be heard (e.g., the sound is played at the right volume) in order for the audio and video systems to meet applicable safety standards.

### SUMMARY

This section provides a general summary of the disclosure and is not a comprehensive disclosure of its full scope or all of its features, aspects or objectives.

According an aspect of the disclosure, an audio system is provided. The audio system includes a system on a chip including a digital signal processor. The digital signal processor has a safety sound memory unit to store a plurality of safety sounds and a plurality of signatures corresponding the plurality of safety sounds. A head unit controller is coupled to the system on a chip and includes a head unit memory unit storing the plurality of signatures and in communication with a vehicle communication bus. The head unit controller includes a signature and volume checker to identify an expected signature of the one of the plurality of safety sounds in response to receiving a message requesting that the one of the plurality of safety sounds be played from the vehicle communication bus. The digital signal processor is configured to output a mixed audio stream. The digital signal processor includes a lower bit inserter to replace a plurality of lower bits of the mixed audio stream with a plurality of replacement lower bits based on one of the plurality of signatures corresponding to the one of the plurality of safety sounds and output a modified audio stream from the system on a chip. A lower bit extractor is coupled to the digital signal processor of the system on a chip and is configured to receive the modified audio stream and separate and output the plurality of replacement lower bits and a remainder of the modified audio stream. An audio amplifier unit is coupled to the lower bit extractor and to at least one vehicle speaker to receive the remainder of the modified audio stream for output with the at least one vehicle speaker. The head unit controller is also coupled to the lower bit extractor and is configured to synchronize the plurality of replacement lower bits from the lower bit extractor to rebuild the one of the plurality of signatures. The head unit controller is also configured to compare the one of the plurality of signatures to the expected signature and determine whether the one of the plurality of signatures matches the expected signature. The head unit controller is additionally configured to send an acknowledgment that the one of the plurality of safety sounds has been played to a vehicle system controller in response to the one of the plurality of signatures matches the expected signature.

According to another aspect of the disclosure, a method of operating an audio system is also provided. The method includes the step of receiving a message requesting that one of the plurality of safety sounds be played using the head unit controller. The next step of the method is identifying an expected signature of the one of the plurality of safety sounds using a signature and volume checker of the head unit controller in response to receiving the message requesting that the one of the plurality of safety sounds be played. The method proceeds by outputting a mixed audio stream using the digital signal processor. The method continues with the step of replacing a plurality of lower bits of the mixed audio stream with a plurality of replacement lower bits based on one of the plurality of signatures corresponding to the one of the plurality of safety sounds being requested using a lower bit inserter coupled to the digital signal processor. Next, outputting a modified audio stream from the lower bit inserter using the digital signal processor. The method also includes the step of receiving the modified audio stream with a lower bit extractor coupled to the digital signal processor of the system on a chip. The method continues by separating the plurality of replacement lower bits and a remainder of the modified audio stream using the lower bit extractor. The method also includes the step of outputting the plurality of replacement lower bits to the head unit controller and the remainder of the modified audio stream using the lower bit extractor. Then, the method includes the step of receiving the remainder of the modified audio stream for output with at least one vehicle speaker using an audio amplifier unit coupled to the at least one vehicle speaker. The method continues with the step of synchronizing the plurality of replacement lower bits to rebuild the one of the plurality of signatures using a synchro decoder of the head unit controller. The method additionally includes the step of comparing the one of the plurality of signatures to the expected signature using the head unit controller. The next step of the method is determining whether the one of the plurality of signatures matches the expected signature using the head unit controller. The method proceeds with the step of sending an acknowledgment that the one of the plurality of safety sounds has been played to a vehicle system controller using the head unit controller in response to the one of the plurality of signatures matching the expected signature.

According to another aspect of the disclosure, a video system is provided. The video system includes a head unit controller in communication with a vehicle communication bus to output a plurality of designated video frames. The head unit includes at least one video output port to output a serial video stream. The head unit includes a video processing unit coupled to the head unit controller to process the plurality of designated video frames into a plurality of display layers. The plurality of display layers has a safety telltale layer including an empty area and a telltale region to display a plurality of safety telltales. The head unit also includes a serializer coupled to the video processing unit to serialize the video output from the video processing unit into a serial video stream on the at least one video output port and confirm that the at least one video output port is operational. At least one display assembly is coupled to the head unit and includes at least one display panel having a display area including at least one region of interest corresponding to one of the plurality of safety telltales to be displayed in a portion of the display area to receive and display the serial video stream from the head unit. The at least one display assembly also includes a deserializer to deserialize the serial video stream from the serializer of the head unit and output an intermediate digital display stream. The at least one display assembly also includes an unpacking unit having a plurality of unpacking unit inputs coupled to the deserializer and at least one unpacking unit output. The unpacking unit is configured to process the intermediate digital display stream from the deserializer and compute a region check sum for the region of interest and communicate the region check sum to the head unit controller of the head unit. The unpacking unit is also configured to output an unpacked digital display output to the at least one display panel. The head unit controller of the head unit is configured to compute an expected region check sum for the serial video stream corresponding to the region of interest and compare the region check sum to the expected region check sum to confirm that the at least one display assembly correctly displays the plurality of safety telltales.

According to yet another aspect of the disclosure, a method of operating a video system is additionally provided. The method includes the step of outputting a plurality of designated video frames using a head unit controller of a head unit. The method continues by processing the plurality of designated video frames into a plurality of display layers including a safety telltale layer including an empty area and a telltale region to display a plurality of safety telltales using a video processing unit of the head unit coupled to the head unit controller. The method then includes the step of serializing the video output from the video processing unit into a serial video stream on the at least one video output port using a serializer of the head unit coupled to the video processing unit. Next, the method includes the step of receiving the serial video stream from the head unit using a deserializer of a display assembly coupled to the display processor. The method additionally includes the step of deserializing the serial video stream from the serializer of the head unit using the deserializer. The method also includes the step of outputting an intermediate digital display stream using the deserializer. The method continues by processing the intermediate digital display stream from the deserializer using an unpacking unit of the at least one display assembly. The method proceeds with the step of computing a region check sum for the region of interest using the unpacking unit. The method then includes the step of communicating the region check sum to the head unit controller of the head unit using the unpacking unit. The method continues with the step of computing an expected region check sum for the serial video stream corresponding to a region of interest associated with one of the plurality of safety telltales to be displayed in a portion of a display area of at least one display panel of the display assembly using the head unit controller. The method additionally includes the step of comparing the region check sum to the expected region check sum using the head unit controller. The method also includes the step of outputting an unpacked digital display output to the at least one display panel using the unpacking unit.

Further areas of applicability will become apparent from the description provided herein. The description and specific examples in this summary are intended for purposes of illustration only and are not intended to limit the scope of the present disclosure.

### BRIEF DESCRIPTION OF THE DRAWINGS

The drawings described herein are for illustrative purposes only of selected embodiments and not all implementations, and are not intended to limit the present disclosure to only that actually shown. With this in mind, various features and advantages of example embodiments of the present disclosure will become apparent from the written description when considered in combination with the appended Figures, wherein:

FIG. 1 illustrates 1 an example system on a chip architecture used by an audio system according to aspects of the disclosure;

FIG. 2 is a block diagram of the audio system including a digital signal processor coupled to a head unit controller according to aspects of the disclosure;

FIGS. 3A-3C and 4A-4B illustrate steps of a method of operating an audio system according to aspects of the disclosure;

FIG. 5 is a block diagram of a video system according to aspects of the disclosure;

FIG. 6 is a block diagram of a video system including a safety icon generator according to aspects of the disclosure; and

FIGS. 7A-7C and 8 illustrate steps of a method of operating a video system according to aspects of the disclosure.

### DETAILED DESCRIPTION

Infotainment and instrumentation in vehicles is typically provided by known audio and video systems. For example, such video systems can include display assemblies for human machine interface (HMI) devices including instrument clusters, heads-up displays (HUDs), and central information displays (CIDs). These display assemblies may all be connected to a single head unit that also provides for much of the audio functionality in the vehicle. To warn the driver and/or passenger about a potential danger, safety sounds (e.g., lane departure, obstacle awareness, too close to an obstacle or another car) may occasionally be played by the audio system. Safety-related information or telltales can also be displayed on display panels of the display assemblies using icons.

In order to make sure that safety-related information is properly conveyed to the vehicle operator and/or passengers, safety requirements such as ISO 26262 have been developed. Consequently, to meet applicable safety standards, it can be advantageous to ensure that any safety related sounds are correctly reproduced for the driver and/or passenger of the vehicle and can be heard (e.g., the sound is played at the right volume). It may also be necessary to confirm or check that the correct telltale is displayed at the right time and place on the appropriate display assembly. Likewise, in order for the audio and video systems. Thus, there is a need for improved audio and video systems for vehicles.

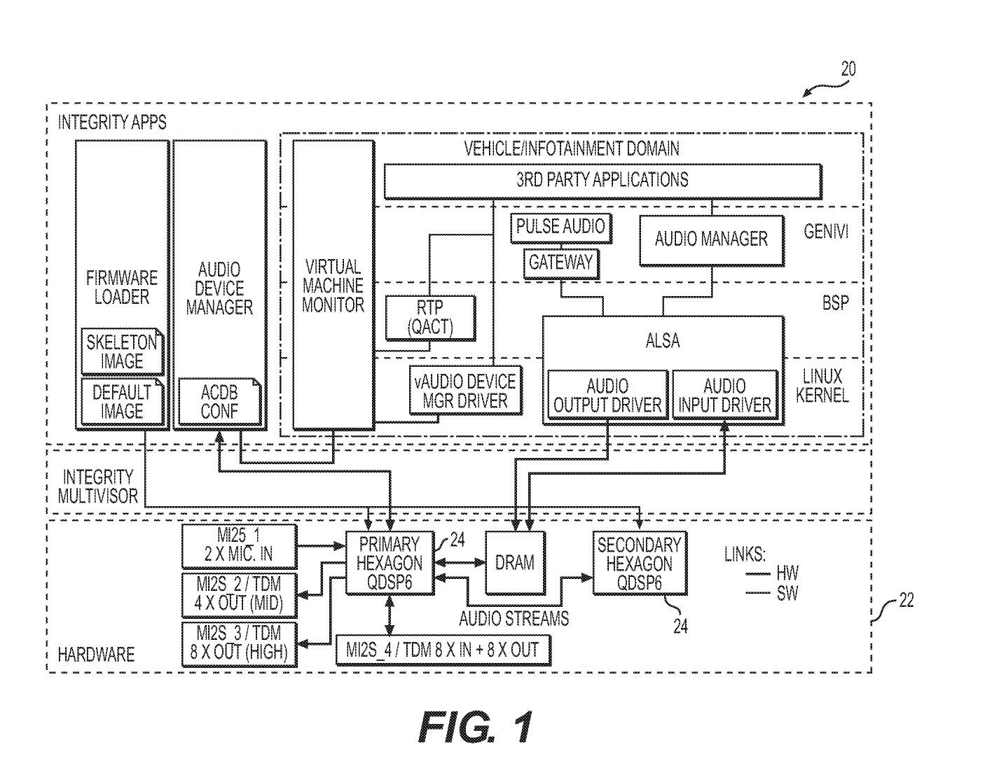

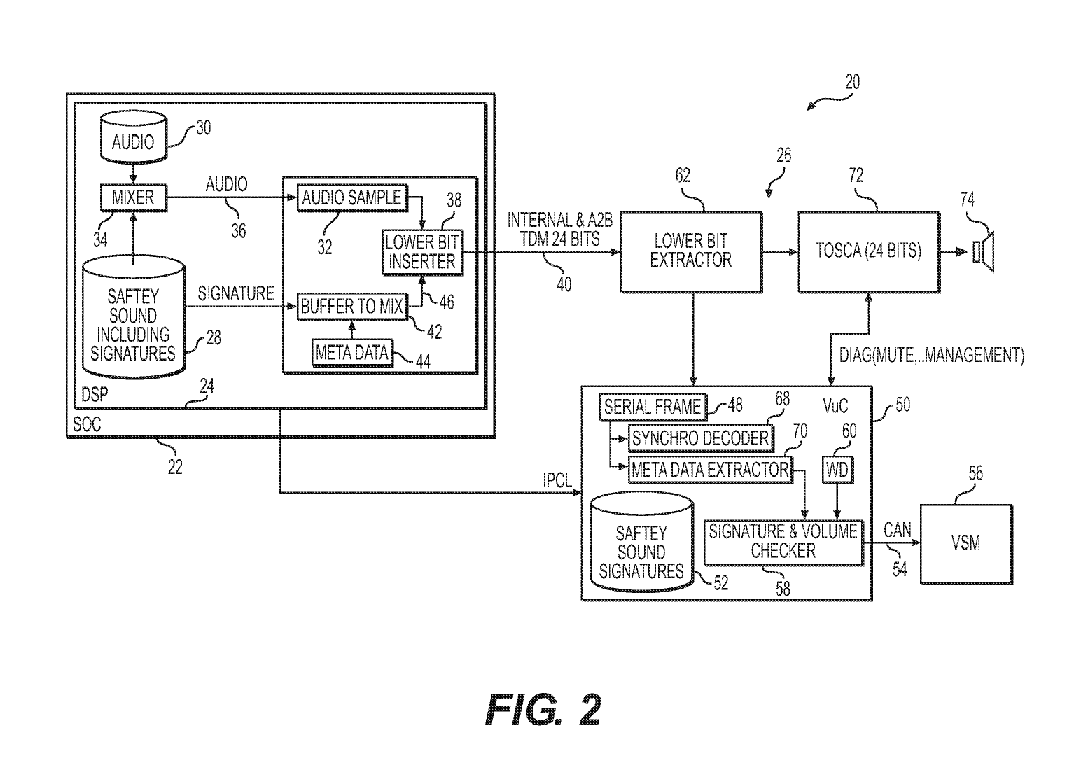

Referring to the Figures, wherein like numerals indicate corresponding parts throughout the several views, an audio system 20 is provided in FIGS. 1 and 2. The audio system 20 includes a system on a chip 22 including a digital signal processor 24 (DSP) as part of a head unit 26. FIG. 1 illustrates an example system on a chip 22 architecture used by the audio system 20. It should be understood that the audio system 20 can, for example, include multiple DSPs 24 as shown in the architecture illustrated in FIG. 1. Referring to FIG. 2, the digital signal processor 24 has a safety sound memory unit 28 (e.g., DRAM unit shown in FIG. 1) to store a plurality of safety sounds and a plurality of signatures corresponding the plurality of safety sounds. So, prior to programming the audio system 20, each specific one of the plurality of safety sounds is associated to a single signature to identify the one of the plurality of safety sounds (e.g., as part of the sound file). The digital signal processor 24 also includes an audio system memory unit 30 to store at least one media sound to be played (e.g., any other media such as music that is to be played by the audio system 20 in the vehicle).

The digital signal processor 24 also includes an audio sample buffer 32 and a mixer unit 34 coupled to the audio system memory unit 30 and the audio sample buffer 32 to mix the one of the plurality of safety sounds from the safety sound memory unit 28 with the at least one media sound and output a mixed audio stream 36 to the audio sample buffer 32. The digital signal processor 24 additionally includes a lower bit inserter 38 coupled to the audio sample buffer 32 to replace a plurality of lower bits of the mixed audio stream 36 with a plurality of replacement lower bits based on one of the plurality of signatures corresponding to the one of the plurality of safety sounds and output a modified audio stream 40 from the system on a chip 22 (i.e., to create a synchro pattern as a lead of a binary frame). The modified audio stream 40 can, for example be communicated over an Automotive Audio Bus (A2B) with Time Division Multiplexing (TDM) using twenty four bits. In more detail, the digital signal processor 24 includes a signature buffer 42 coupled to the safety sound memory unit 28. The digital signal processor 24 is configured to assemble the one of the plurality of signatures corresponding to the one of the plurality of safety sounds being requested from the safety sound memory unit 28 and meta data from a meta data unit 44 in the signature buffer 42 to form a signature stream 46 (e.g., a binary frame) for use by the lower bit inserter 38 in replacing the plurality of lower bits of the mixed audio stream 36 with the plurality of replacement lower bits. The meta data can include additional information about the one of the plurality of safety sounds being played, such as, but not limited to mixer state and volume. Therefore, the binary or serial frame 48 is sent bit-by-bit along with the one of the mixed audio stream 36 including the plurality of safety sounds (i.e., the plurality of lower bits are replaced by one bit of the binary frame, then the next bit of the binary frame replaces the lower bit of the next sound sample, and so on). Sound quality is not significantly impacted by the plurality replacement bits, since only one bit is affected. For example, it may be recommended to keep at least sixteen bits for audio; however, that may be reduced to fifteen bits, since the sound quality would only be affected when the one of the plurality of safety sounds is being played. As disclosed herein, twenty four bits are utilized, and therefore twenty three bits are available for the audio.

A head unit controller 50 is coupled to the system on a chip 22 and includes a head unit memory unit 52 storing the plurality of signatures and is in communication with a vehicle communication bus 54 (e.g., controller area network or CAN bus for communication with a vehicle system controller 56). The head unit controller 50 includes a signature and volume checker 58 to identify an expected signature of the one of the plurality of safety sounds in response to receiving a message requesting that the one of the plurality of safety sounds be played from the vehicle communication bus 54. A watch dog unit 60 is also coupled to the signature and volume checker 58. The signature and volume checker 58 of the head unit controller 50 can also determine an expected volume of the one of the plurality of safety sounds in response to receiving the message requesting that the one of the plurality of safety sounds be played. So, the head unit controller 50 identifies both the expected signature, as described above, and other safety related data (e.g., expected volume) from the message requesting that the one of the plurality of safety sounds be played.

A lower bit extractor 62 is coupled to the digital signal processor 24 of the system on a chip 22 and is configured to receive the modified audio stream 40. The lower bit extractor 62 separates and outputs the plurality of replacement lower bits and a remainder of the modified audio stream 40 (e.g., using TDM over A2B).

The head unit controller 50 is also coupled to the lower bit extractor 62 and is configured to synchronize the plurality of replacement lower bits from the lower bit extractor 62 to rebuild the one of the plurality of signatures. More specifically, the head unit controller 50 includes a synchro decoder 68 to synchronize the plurality of replacement lower bits and a meta data extractor 70 to extract the meta data from the plurality of replacement lower bits (from the serial frame 48 that is rebuilt). The head unit controller 50 can then determine if a reconstructed volume of the meta data matches with the expected volume. As a result, the head unit controller 50 can send an acknowledgment to the vehicle system controller 56 in response to the reconstructed volume of the meta data matching the expected volume. This can ensure that the volume of the one of the plurality of safety sounds is at the correct level relative to other audio signals in the vehicle, such as the radio or media from a memory stick, for example. As indicated above, other information can also be contained in the meta data, such as the mixer status.

The head unit controller 50 is also configured to compare the one of the plurality of signatures to the expected signature and determine whether the one of the plurality of signatures matches the expected signature. Consequently, the head unit controller 50 is additionally configured to send an acknowledgment that the one of the plurality of safety sounds has been played to a vehicle system controller 56 in response to the one of the plurality of signatures matches the expected signature. However, in the event that the one of the plurality of signatures does not match the expected signature and/or the reconstructed volume of the meta data does not match the expected volume, the head unit controller 50 is further configured to transfer the one of the plurality of safety sounds to a steering wheel buzzer (not shown). Alternatively, the system could attempt to replay the one of the plurality of safety sounds, for example. The head unit controller 50 can also request to mute an audio amplifier unit 72 (discussed below) in response to at least one of the one of the plurality of signatures not matching the expected signature and the reconstructed volume of the meta data not matching the expected volume (e.g., within a predetermined amount of time).

The audio amplifier unit 72 is coupled to the lower bit extractor 62 and to at least one vehicle speaker 74 to receive the remainder of the modified audio stream 40 for output with the at least one vehicle speaker 74. Diagnostic information or data can be made available and output from the audio amplifier unit 72. Specifically, the audio amplifier unit 72 can have a self-diagnostic to ensure that sound is correctly emitted from the at least one vehicle speaker 74. Thus, the head unit controller 50 is additionally configured to receive and check diagnostic data from the audio amplifier unit 72. As a result, the disclosed audio system 20 can ensure that the one of the plurality of safety sounds is played, not another one, and can ensure that the volume of the one of the plurality of safety sounds compared to any other sounds being played is high enough, so that it can be heard by the driver and/or the passenger.

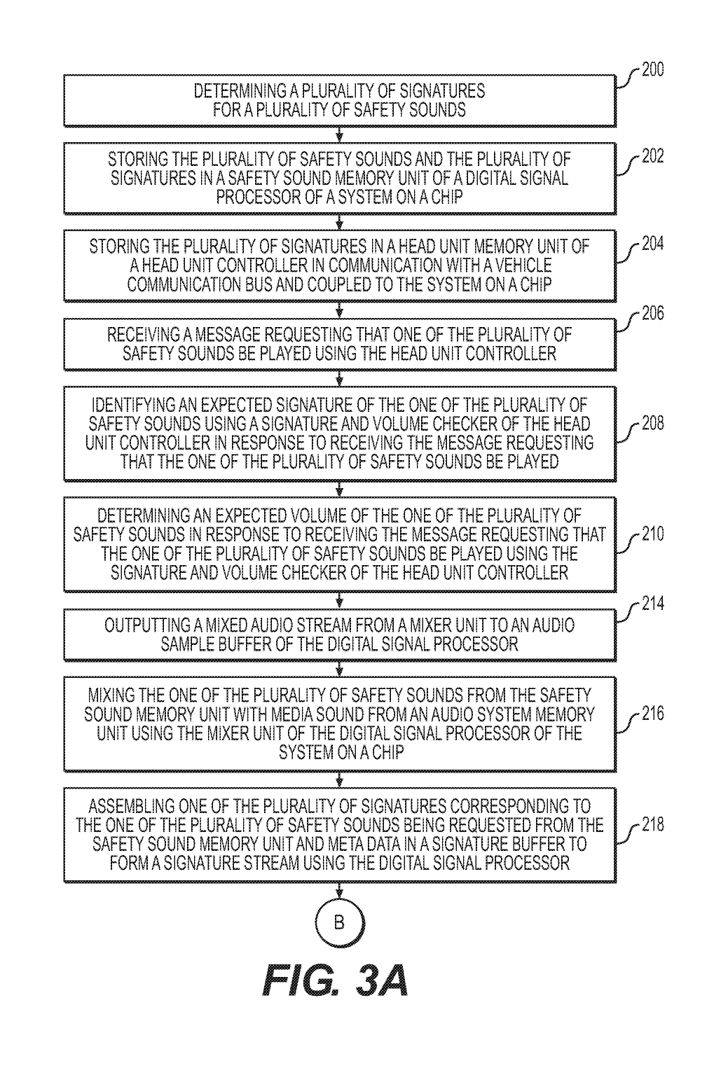

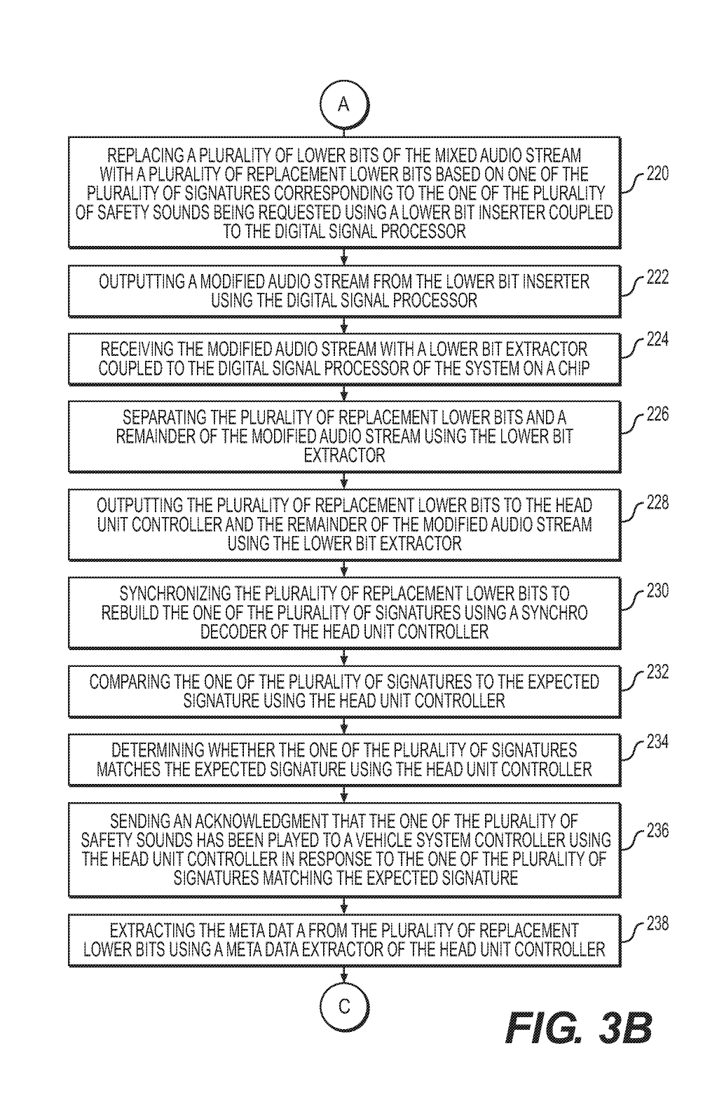

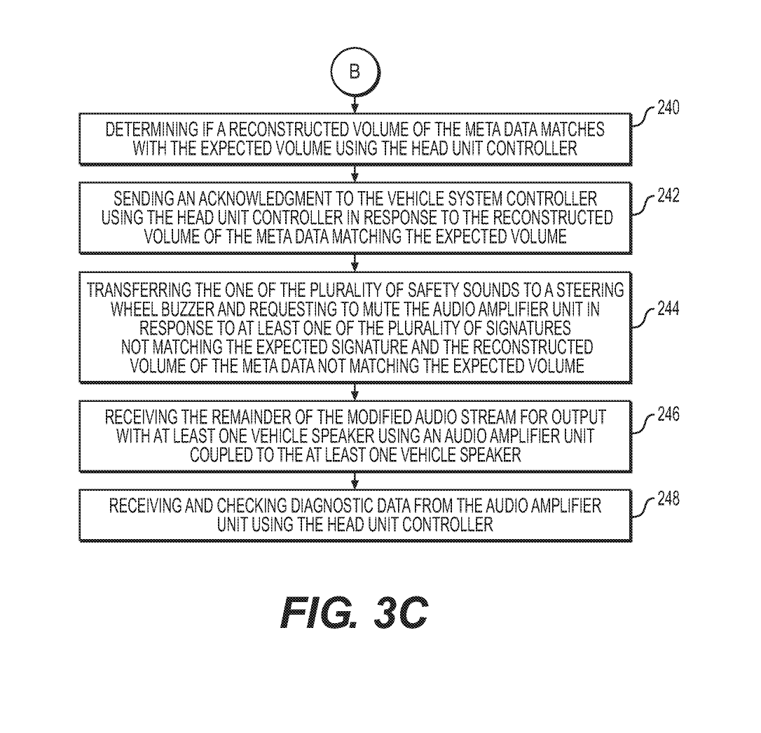

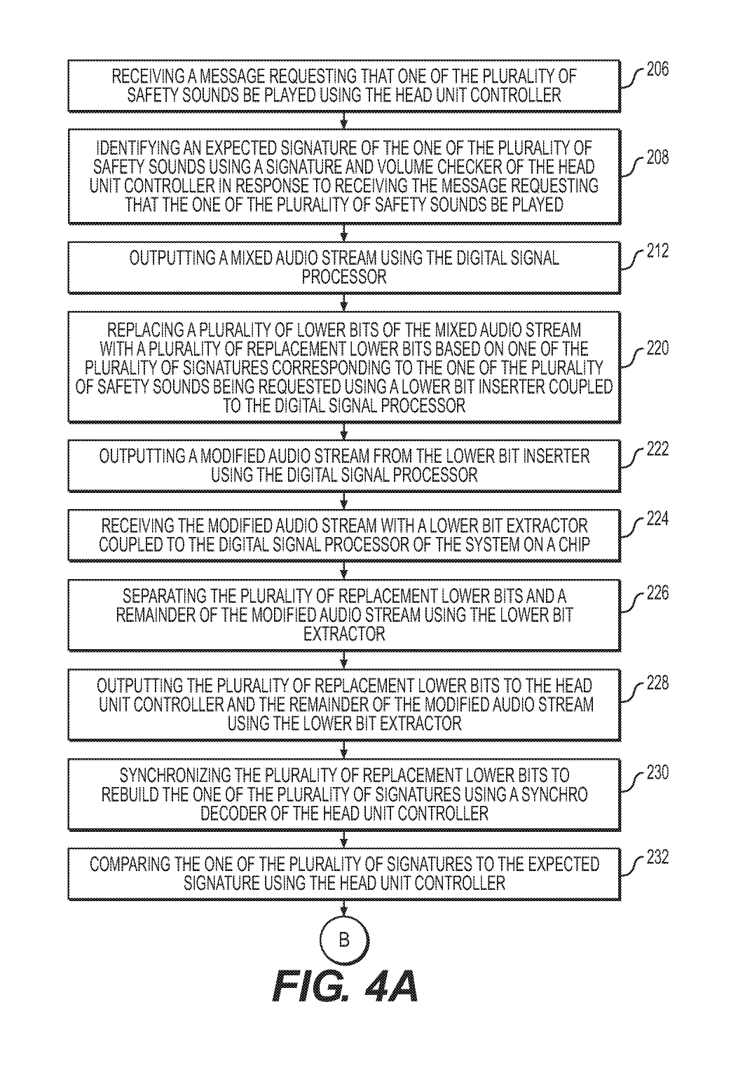

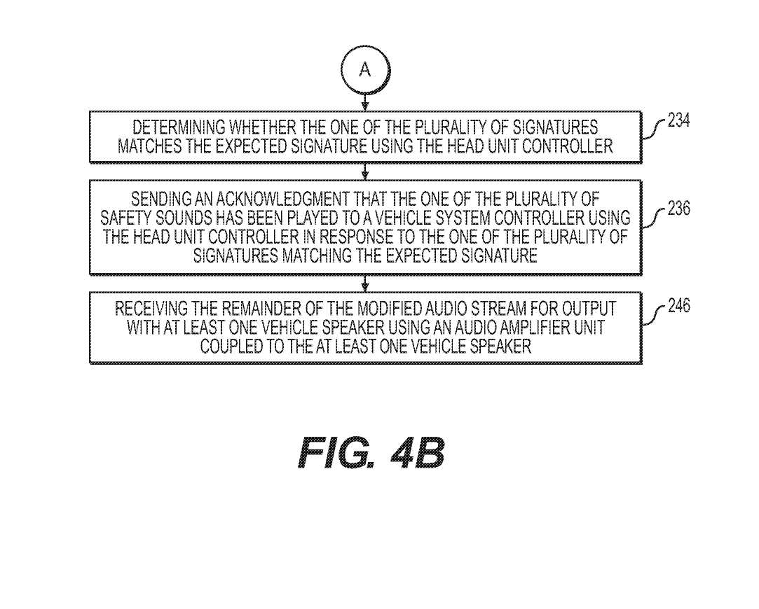

As best shown in FIGS. 3A-3C and 4A-4B, a method of operating an audio system 20 is also provided. The method includes the step of 200 determining a plurality of signatures for a plurality of safety sounds. The method proceeds by 202 storing the plurality of safety sounds and the plurality of signatures in a safety sound memory unit 28 of a digital signal processor 24 of a system on a chip 22. The next step of the method is 204 storing the plurality of signatures in a head unit memory unit 52 of a head unit controller 50 in communication with a vehicle communication bus 54 and coupled to the system on a chip 22.

The method of operating the audio system 20 continues with the step of 206 receiving a message requesting that one of the plurality of safety sounds be played using the head unit controller 50. The next step of the method is 208 identifying an expected signature of the one of the plurality of safety sounds using a signature and volume checker 58 of the head unit controller 50 in response to receiving the message requesting that the one of the plurality of safety sounds be played. Specifically, the method can include the step of 210 determining an expected volume of the one of the plurality of safety sounds in response to receiving the message requesting that the one of the plurality of safety sounds be played using the signature and volume checker 58 of the head unit controller 50.

The method proceeds by 212 outputting a mixed audio stream 36 using the digital signal processor 24. In more detail, the step of 212 outputting the mixed audio stream 36 using the digital signal processor 24 can include 214 outputting a mixed audio stream 36 from a mixer unit 34 to an audio sample buffer 32 of the digital signal processor 24. Then, the method can further include the step of 216 mixing the one of the plurality of safety sounds from the safety sound memory unit 28 with media sound from an audio system memory unit 30 using the mixer unit 34 of the digital signal processor 24 of the system on a chip 22. The method can also include the step of 218 assembling one of the plurality of signatures corresponding to the one of the plurality of safety sounds being requested from the safety sound memory unit 28 and meta data in a signature buffer 42 to form a signature stream 46 using the digital signal processor 24.

The method additionally includes the step of 220 replacing a plurality of lower bits of the mixed audio stream 36 with a plurality of replacement lower bits based on one of the plurality of signatures corresponding to the one of the plurality of safety sounds being requested using a lower bit inserter 38 coupled to the digital signal processor 24. Next, 222 outputting a modified audio stream 40 from the lower bit inserter 38 using the digital signal processor 24. The method also includes the step of 224 receiving the modified audio stream 40 with a lower bit extractor 62 coupled to the digital signal processor 24 of the system on a chip 22. The method continues by 226 separating the plurality of replacement lower bits and a remainder of the modified audio stream 40 using the lower bit extractor 62. The method also includes the step of 228 outputting the plurality of replacement lower bits to the head unit controller 50 and the remainder of the modified audio stream 40 using the lower bit extractor 62.

The method proceeds with the step of 230 synchronizing the plurality of replacement lower bits to rebuild the one of the plurality of signatures using a synchro decoder 68 of the head unit controller 50. The method additionally includes the step of 232 comparing the one of the plurality of signatures to the expected signature using the head unit controller 50. The next step of the method is 234 determining whether the one of the plurality of signatures matches the expected signature using the head unit controller 50. The method proceeds with the step of 236 sending an acknowledgment that the one of the plurality of safety sounds has been played to a vehicle system controller 56 using the head unit controller 50 in response to the one of the plurality of signatures matching the expected signature.

The method can also include the step of 238 extracting the meta data from the plurality of replacement lower bits using a meta data extractor 70 of the head unit controller 50. Then, 240 determining if a reconstructed volume of the meta data matches with the expected volume using the head unit controller 50. The method can also include the step of 242 sending an acknowledgment to the vehicle system controller 56 using the head unit controller 50 in response to the reconstructed volume of the meta data matching the expected volume. If the one of the plurality of signatures does not match the expected signature and/or the reconstructed volume of the meta data does not match the expected volume, the audio system 20 can still make sure that a the one of the plurality of safety sounds is reproduced. Thus, the method can include the steps of 244 transferring the one of the plurality of safety sounds to a steering wheel buzzer and requesting to mute the audio amplifier unit 72 in response to at least one of the one of the plurality of signatures not matching the expected signature and the reconstructed volume of the meta data not matching the expected volume.

The method continues with the step of 246 receiving the remainder of the modified audio stream 40 for output with at least one vehicle speaker 74 using an audio amplifier unit 72 coupled to the at least one vehicle speaker 74. As discussed above, diagnostic information data can be made available and output from the audio amplifier unit 72, so the method can also include the step of 248 receiving and checking diagnostic data from the audio amplifier unit 72 using the head unit controller 50.

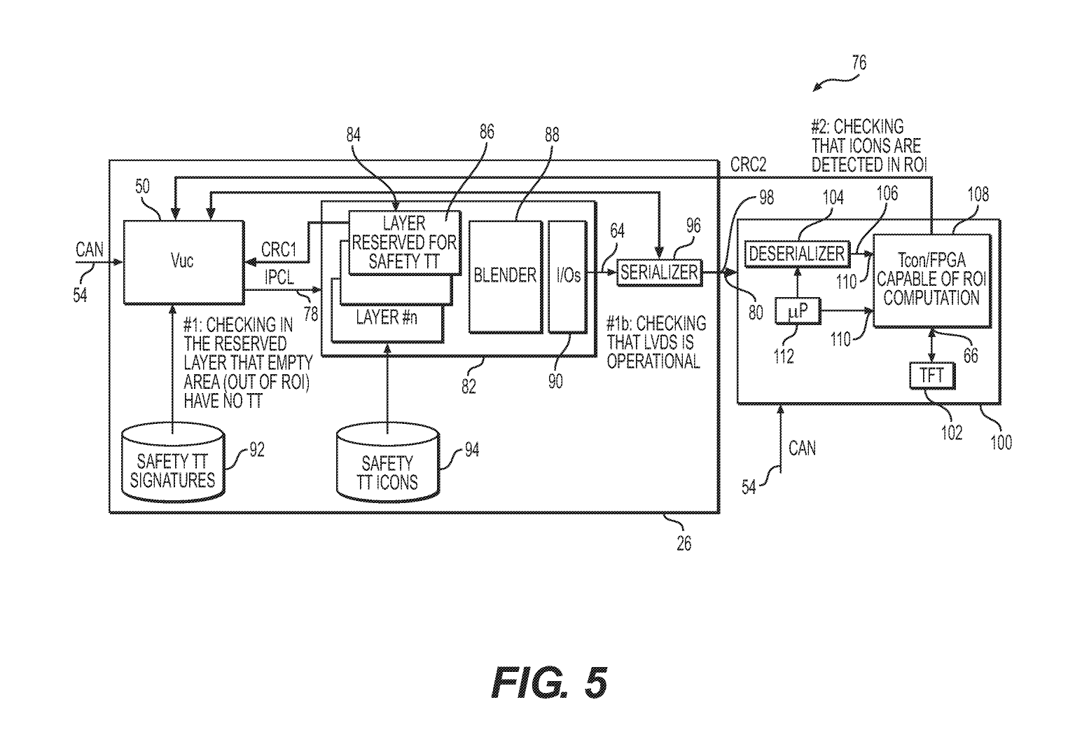

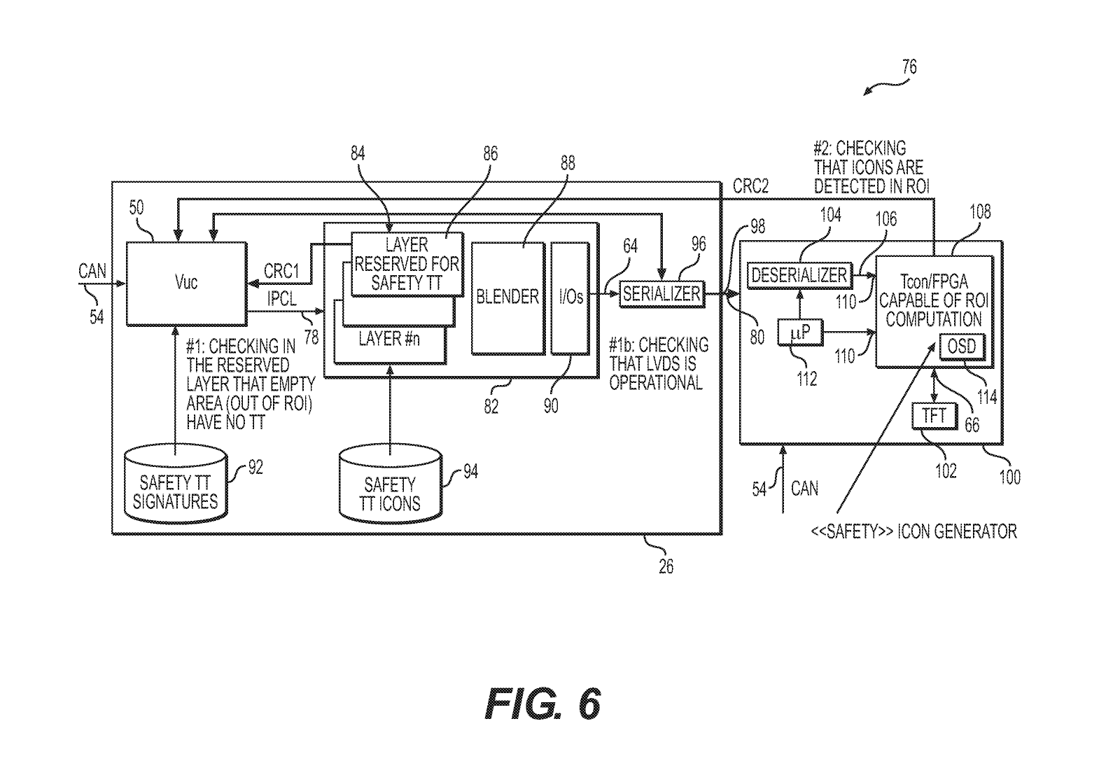

A video system 76 is provided in FIGS. 5 and 6. The video system 76 includes the head unit 26 having the head unit controller 50 (this can be the same head unit controller 50 as in the audio system 20 described above, or a different controller) in communication with the vehicle communication bus 54 (e.g., CAN bus) to output a plurality of designated video frames 78. The head unit 26 includes at least one video output port 98 to output a serial video stream 80.

The head unit 26 also includes a video processing unit 82 coupled to the head unit controller 50 to process the plurality of designated video frames 78 into a plurality of display layers 84. The plurality of display layers 84 includes a safety telltale layer 86 that has an empty area and a telltale region to display a plurality of safety telltales. So, the plurality of safety telltales are supposed to be displayed in predefined locations. The video processing unit 82 includes a blender 88 for blending the plurality of display layers 84 and a processing input and output module 90 for packing the plurality of designated video frames 78 and outputting a video output 64. According to aspect, the highest priority graphical layer can be reserved for the safety telltale layer 86. The video processing unit 82 is configured to compute a layer check sum CRC1 for the safety telltale layer 86 and communicate the layer check sum CRC1 to the head unit controller 50 of the head unit 26.

The head unit 26 includes a safety telltale signature memory unit 92 coupled to the head unit controller 50 to store a plurality of safety telltale signatures corresponding the plurality of safety telltales to be displayed and a safety telltale icon memory unit 94 coupled to the video processing unit 82 to store the plurality of safety telltales. The head unit 26 also includes a serializer 96 coupled to the video processing unit 82 to serialize the video output 64 from the video processing unit 82 into the serial video stream 80 on the at least one video output port 98 and confirm that the at least one video output port 98 is operational.

At least one display assembly 100 (e.g., an instrument cluster) is coupled to the head unit 26 and includes at least one display panel 102 having a display area including at least one region of interest corresponding to one of the plurality of safety telltales to be displayed in a portion of the display area to receive and display the serial video stream 80 from the head unit 26. The at least one display assembly 100 also includes a deserializer 104 to deserialize the serial video stream 80 from the serializer 96 of the head unit 26 and output an intermediate digital display stream 106.

The at least one display assembly 100 also includes an unpacking unit 108 having a plurality of unpacking unit inputs 110 coupled to the deserializer 104 and at least one unpacking unit output 66. The unpacking unit 108 can, for example, be a Field Programmable Gate Array (FPGA) or Tunable Connections (TCON), however, it should be understood that the unpacking unit 108 can be implemented in alternative ways. The at least one display assembly 100 includes a display processor 112 coupled to the unpacking unit 108 and to the deserializer 104 to control the at least one display assembly 100. The unpacking unit 108 is configured to process the intermediate digital display stream 106 from the deserializer 104 and compute a region check sum CRC2 for the region of interest and communicate the region check sum CRC2 to the head unit controller 50 of the head unit 26. The unpacking unit 108 is also configured to output an unpacked digital display output to the at least one display panel 102.

The head unit controller 50 of the head unit 26 is configured to compute an expected region check sum for the serial video stream 80 corresponding to the region of interest. Alternatively, the expected region check sum can be determined ahead of time and stored in the head unit 26. The head unit controller 50 compares the region check sum CRC2 to the expected region check sum to confirm that the at least one display assembly 100 correctly displays the plurality of safety telltales. The head unit controller 50 also computes an expected layer check sum corresponding to the telltale region of the safety telltale layer 86 in the video processing unit 82. As with the expected region check sum, the expected layer check sum can be determined ahead of time and stored in the head unit 26. In either event, the head unit controller 50 compares the layer check sum CRC1 to the expected layer check sum. The head unit controller 50 can also check to ensure that none of the plurality of safety telltales are in the empty area of the safety telltale layer 86. The use of the check sums CRC1, CRC2 can ensure that even if the output of the blender 88 and/or processing input and output module 90 is altered (e.g., the safety telltale layer 86 is not mixed properly by the blender 88), the video system 76 can make sure that the plurality of safety telltales are displayed properly.

According to an aspect, as best shown in FIG. 6, the unpacking unit 108 can additionally include a safety icon generator 114 (i.e., text/graphical generator). In the event that the head unit controller 50 determines that the layer check sum CRC1 does not match the expected layer check sum and/or the region check sum CRC2 does not match the expected region check sum, the head unit controller 50 or another vehicle system controller 56 can request that the at least one display assembly 100 displays the at least one safety telltale using the safety icon generator 114 of the unpacking unit 108.

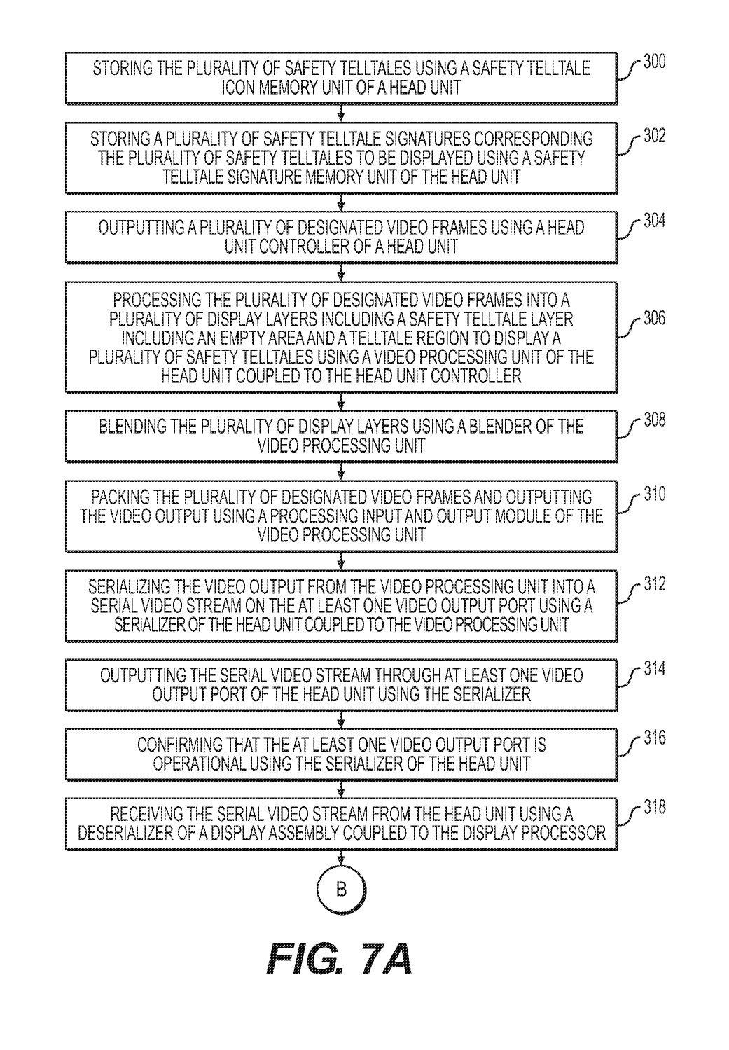

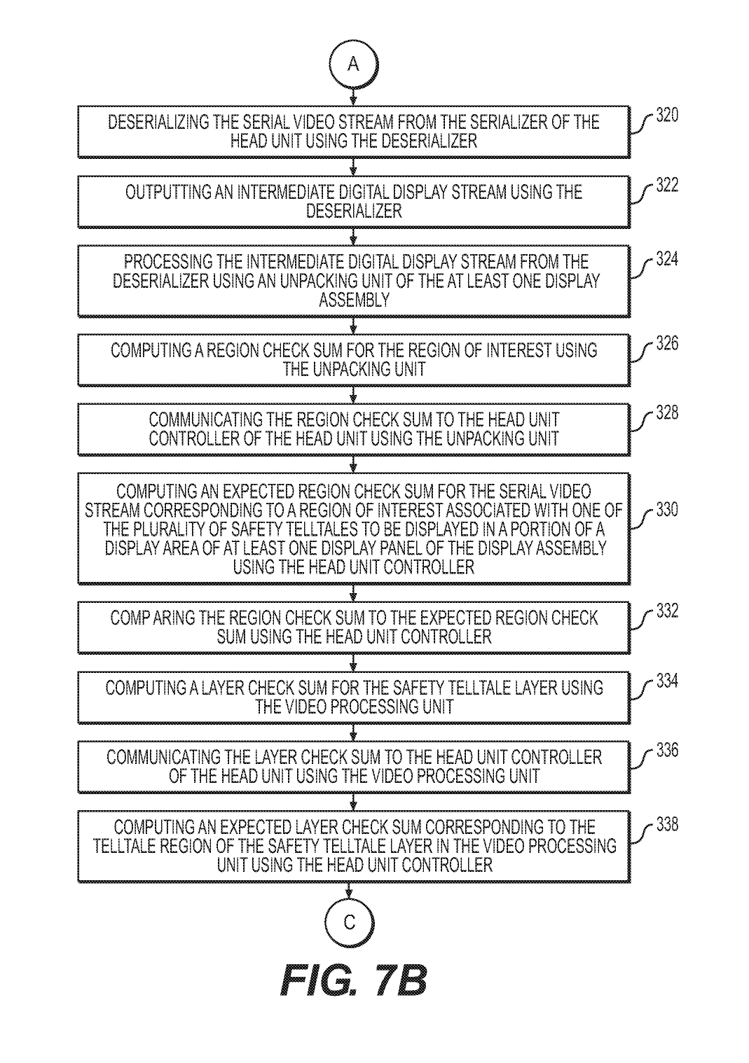

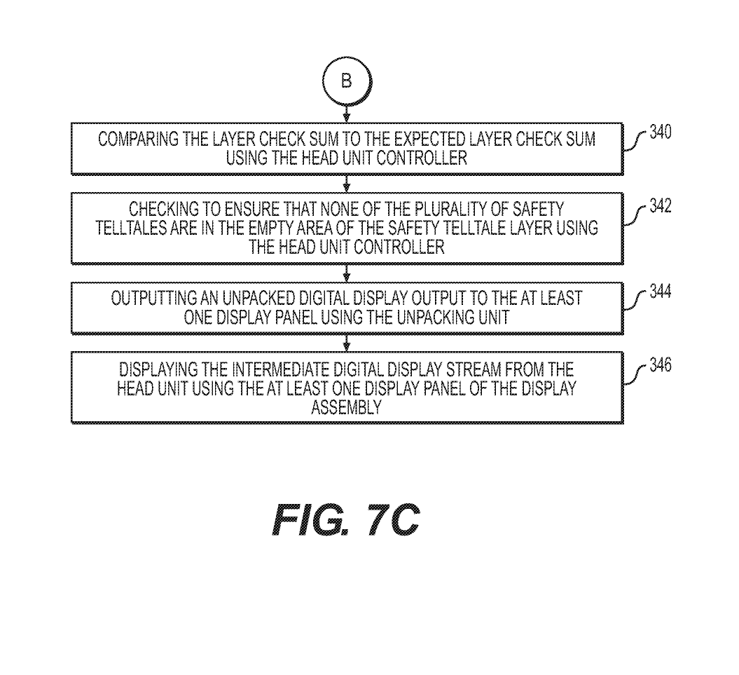

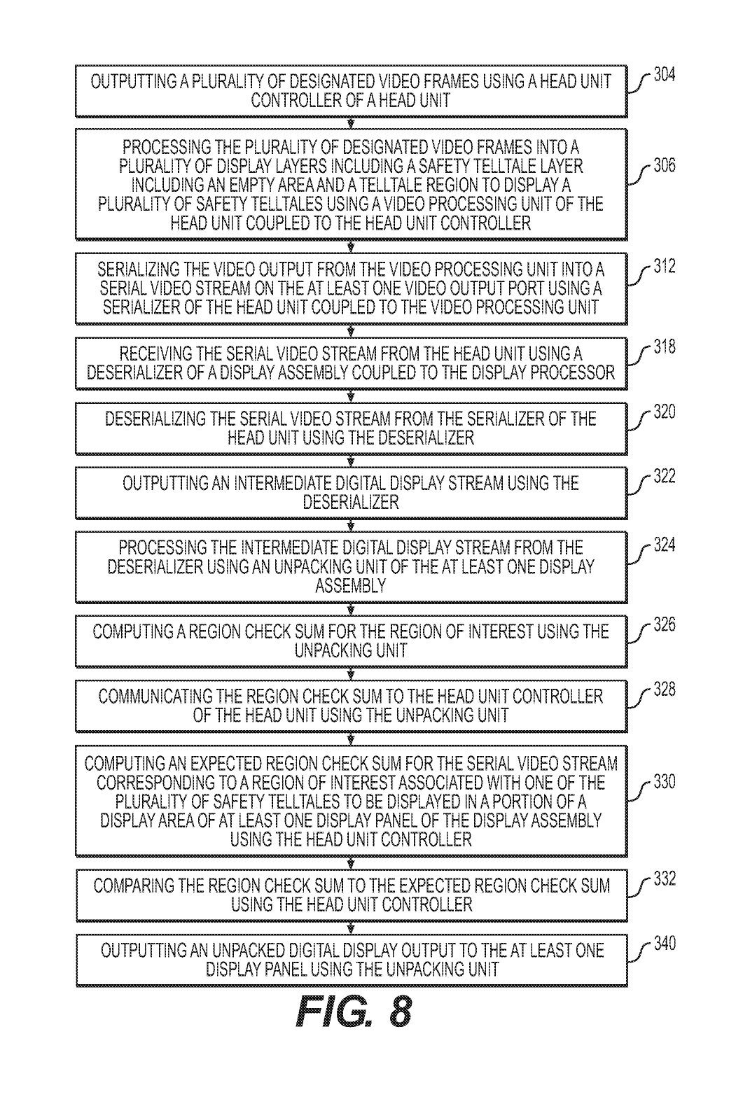

As best shown in FIGS. 7A-7C and 8, a method of operating a video system 76 is additionally provided. The method includes the steps of 300 storing the plurality of safety telltales using a safety telltale icon memory unit 94 of a head unit 26 and 302 storing a plurality of safety telltale signatures corresponding the plurality of safety telltales to be displayed using a safety telltale signature memory unit 92 of the head unit 26. The method then includes the step of 304 outputting a plurality of designated video frames 78 using a head unit controller 50 of a head unit 26.

The method continues by 306 processing the plurality of designated video frames 78 into a plurality of display layers 84 including a safety telltale layer 86 including an empty area and a telltale region to display a plurality of safety telltales using a video processing unit 82 of the head unit 26 coupled to the head unit controller 50. The method can also include the steps of 308 blending the plurality of display layers 84 using a blender 88 of the video processing unit 82 and 310 packing the plurality of designated video frames 78 and outputting the video output 64 using a processing input and output module 90 of the video processing unit 82.

The method then includes the step of 312 serializing the video output 64 from the video processing unit 82 into a serial video stream 80 on the at least one video output port 98 using a serializer 96 of the head unit 26 coupled to the video processing unit 82. The method proceeds by 314 outputting the serial video stream 80 through at least one video output port 98 of the head unit 26 using the serializer 96. The method may also include the step of 316 confirming that the at least one video output port 98 is operational using the serializer 96 of the head unit 26.

Next, the method includes the step of 318 receiving the serial video stream 80 from the head unit 26 using a deserializer 104 of a display assembly 100 coupled to the display processor 112. The method additionally includes the step of 320 deserializing the serial video stream 80 from the serializer 96 of the head unit 26 using the deserializer 104. The method also includes the step of 322 outputting an intermediate digital display stream 106 using the deserializer 104.

The method continues by 324 processing the intermediate digital display stream 106 from the deserializer 104 using an unpacking unit 108 of the at least one display assembly 100. The method proceeds with the step of 326 computing a region check sum CRC2 for the region of interest using the unpacking unit 108. The method then includes the step of 328 communicating the region check sum CRC2 to the head unit controller 50 of the head unit 26 using the unpacking unit 108. The method continues with the step of 330 computing an expected region check sum for the serial video stream 80 corresponding to a region of interest associated with one of the plurality of safety telltales to be displayed in a portion of a display area of at least one display panel 102 of the display assembly 100 using the head unit controller 50. The method also includes the step of 332 comparing the region check sum CRC2 to the expected region check sum using the head unit controller 50.

Because the video system 76 can additionally include the use of a layer check sum CRC1, the method can include 334 computing a layer check sum CRC1 for the safety telltale layer 86 using the video processing unit 82. Then, the method can include the step of 336 communicating the layer check sum CRC1 to the head unit controller 50 of the head unit 26 using the video processing unit 82. Next, 338 computing an expected layer check sum corresponding to the telltale region of the safety telltale layer 86 in the video processing unit 82 using the head unit controller 50. The method continues by 340 comparing the layer check sum CRC1 to the expected layer check sum using the head unit controller 50. The next step of the method is 342 checking to ensure that none of the plurality of safety telltales are in the empty area of the safety telltale layer 86 using the head unit controller 50. The method also includes the step of 344 outputting an unpacked digital display output to the at least one display panel 102 using the unpacking unit 108. The method then includes the step of 346 displaying the unpacked digital display output from the unpacking unit 108 using the at least one display panel 102 of the display assembly 100.

Embodiments disclosed herein can be implemented in digital electronic circuitry, or in computer software, firmware, or hardware, including the herein disclosed structures and their equivalents. Some embodiments can be implemented as one or more computer programs, i.e., one or more modules of computer program instructions, encoded on a tangible computer storage medium for execution by one or more processors (e.g., voice processor or classification processor). A computer storage medium (e.g., the data store of the voice user interface module 24) can be, or can be included in, a computer-readable storage device, a computer-readable storage substrate, or a random or serial access memory. The computer storage medium can also be, or can be included in, one or more separate tangible components or media such as multiple CDs, disks, or other storage devices. The computer storage medium does not include a transitory signal.

As used herein, the term processor or controller encompasses all kinds of apparatus, devices, and machines for processing data, including by way of example a programmable processor, a computer, a system on a chip, or multiple ones, or combinations, of the foregoing. The processor can include special purpose logic circuitry, e.g., an FPGA or an ASIC (application-specific integrated circuit). The processor or controller also can include, in addition to hardware, code that creates an execution environment for the computer program in question, e.g., code that constitutes processor firmware, a protocol stack, a database management system, an operating system, a cross-platform runtime environment, a virtual machine, or a combination of one or more of them.

A computer program (also known as a program, module, engine, software, software application, application, script, or code) can be written in any form of programming language, including compiled or interpreted languages, declarative or procedural languages, and the program can be deployed in any form, including as a stand-alone program or as a module, component, subroutine, object, or other unit suitable for use in a computing environment. A computer program may, but need not, correspond to a file in a file system. A program can be stored in a portion of a file that holds other programs or data (e.g., one or more scripts stored in a markup language document), in a single file dedicated to the program in question, or in multiple coordinated files (e.g., files that store one or more modules, sub-programs, or portions of code). A computer program can be deployed to be executed on one computer or on multiple computers that are located at one site or distributed across multiple sites and interconnected by a communication network.

Obviously, many modifications and variations of the claimed invention are possible in light of the above teachings and may be practiced otherwise than as specifically described while within the scope of the appended claims. These antecedent recitations should be interpreted to cover any combination in which the inventive novelty exercises its utility.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated degrees or at other orientations) and the spatially relative descriptions used herein interpreted accordingly.

1. An audio system, comprising:
a system on a chip including a digital signal processor having a safety sound memory unit to store a plurality of safety sounds and a plurality of signatures corresponding the plurality of safety sounds;
a head unit controller coupled to the system on a chip and including a head unit memory unit storing the plurality of signatures and in communication with a vehicle communication bus;
the head unit controller including a signature and volume checker to identify an expected signature of the one of the plurality of safety sounds in response to receiving a message requesting that the one of the plurality of safety sounds be played from the vehicle communication bus;
the digital signal processor configured to output a mixed audio stream and including a lower bit inserter to replace a plurality of lower bits of the mixed audio stream with a plurality of replacement lower bits based on one of the plurality of signatures corresponding to the one of the plurality of safety sounds and output a modified audio stream from the system on a chip;
a lower bit extractor coupled to the digital signal processor of the system on a chip and configured to receive the modified audio stream and separate and output the plurality of replacement lower bits and a remainder of the modified audio stream;
an audio amplifier unit coupled to the lower bit extractor and to at least one vehicle speaker to receive the remainder of the modified audio stream for output with the at least one vehicle speaker;
the head unit controller coupled to the lower bit extractor and configured to: synchronize the plurality of replacement lower bits from the lower bit extractor to
rebuild the one of the plurality of signatures,
compare the one of the plurality of signatures to the expected signature,
determine whether the one of the plurality of signatures matches the expected signature, and
send an acknowledgment that the one of the plurality of safety sounds has been played to a vehicle system controller in response to the one of the plurality of signatures matches the expected signature.

2. The system as set forth in claim 1, wherein the digital signal processor further includes an audio system memory unit to store at least one media sound to be played and an audio sample buffer coupled to the lower bit inserter and a mixer unit coupled to the audio system memory unit and the audio sample buffer to mix the one of the plurality of safety sounds from the safety sound memory unit with the at least one media sound and output a mixed audio stream from the mixer unit to the audio sample buffer.

3. The system as set forth in claim 2, wherein the digital signal processor includes a signature buffer coupled to the safety sound memory unit and the digital signal processor is configured to assemble the one of the plurality of signatures corresponding to the one of the plurality of safety sounds being requested from the safety sound memory unit and meta data in the signature buffer to form a signature stream for use by the lower bit inserter in replacing the plurality of lower bits of the mixed audio stream with the plurality of replacement lower bits.

4. The system as set forth in claim 1, wherein the head unit controller includes a synchro decoder to synchronize the plurality of replacement lower bits and a meta data extractor to extract the meta data from the plurality of replacement lower bits and the signature and volume checker of the head unit controller determines an expected volume of the one of the plurality of safety sounds in response to receiving the message requesting that the one of the plurality of safety sounds be played and determines if a reconstructed volume of the meta data matches with the expected volume and send an acknowledgment to the vehicle system controller in response to the reconstructed volume of the meta data matching the expected volume.

5. The system as set forth in claim 4, wherein the head unit controller is further configured to transfer the one of the plurality of safety sounds to a steering wheel buzzer and request to mute the audio amplifier unit in response to at least one of the one of the plurality of signatures not matching the expected signature and the reconstructed volume of the meta data not matching the expected volume.

6. The system as set forth in claim 1, wherein the head unit controller is further configured to receive and check diagnostic data from the audio amplifier unit.

7. A method of operating an audio system comprising the steps of:
receiving a message requesting that one of the plurality of safety sounds be played using the head unit controller;
identifying an expected signature of the one of the plurality of safety sounds using a signature and volume checker of the head unit controller in response to receiving the message requesting that the one of the plurality of safety sounds be played;
outputting a mixed audio stream using the digital signal processor;
replacing a plurality of lower bits of the mixed audio stream with a plurality of replacement lower bits based on one of the plurality of signatures corresponding to the one of the plurality of safety sounds being requested using a lower bit inserter coupled to the digital signal processor;
outputting a modified audio stream from the lower bit inserter using the digital signal processor;
receiving the modified audio stream with a lower bit extractor coupled to the digital signal processor of the system on a chip;
separating the plurality of replacement lower bits and a remainder of the modified audio stream using the lower bit extractor;
outputting the plurality of replacement lower bits to the head unit controller and the remainder of the modified audio stream using the lower bit extractor;
synchronizing the plurality of replacement lower bits to rebuild the one of the plurality of signatures using a synchro decoder of the head unit controller;
comparing the one of the plurality of signatures to the expected signature using the head unit controller;
determining whether the one of the plurality of signatures matches the expected signature using the head unit controller;
sending an acknowledgment that the one of the plurality of safety sounds has been played to a vehicle system controller using the head unit controller in response to the one of the plurality of signatures matching the expected signature; and
receiving the remainder of the modified audio stream for output with at least one vehicle speaker using an audio amplifier unit coupled to the at least one vehicle speaker.

8. The method as set forth in claim 7, further including the steps of: determining a plurality of signatures for a plurality of safety sounds;
storing the plurality of safety sounds and the plurality of signatures in a safety sound memory unit of a digital signal processor of a system on a chip; and
storing the plurality of signatures in a head unit memory unit of a head unit controller in communication with a vehicle communication bus and coupled to the system on a chip.

9. The method as set forth in claim 7, wherein the step of outputting the mixed audio stream using the digital signal processor includes outputting a mixed audio stream from a mixer unit to an audio sample buffer of the digital signal processor and the method further including the steps of:
mixing the one of the plurality of safety sounds from the safety sound memory unit with media sound from an audio system memory unit using the mixer unit of the digital signal processor of the system on a chip; and
assembling one of the plurality of signatures corresponding to the one of the plurality of safety sounds being requested from the safety sound memory unit and meta data in a signature buffer to form a signature stream using the digital signal processor; and
extracting the meta data from the plurality of replacement lower bits using a meta data extractor of the head unit controller.

10. The method as set forth in claim 7, further including the step of receiving and checking diagnostic data from the audio amplifier unit using the head unit controller.

11. The method as set forth in claim 7, further including the steps of:
determining an expected volume of the one of the plurality of safety sounds in response to receiving the message requesting that the one of the plurality of safety sounds be played using the signature and volume checker of the head unit controller;
determining if a reconstructed volume of the meta data matches with the expected volume using the head unit controller; and
sending an acknowledgment to the vehicle system controller using the head unit controller in response to the reconstructed volume of the meta data matching the expected volume.

12. The method as set forth in claim 11, further including the step of transferring the one of the plurality of safety sounds to a steering wheel buzzer and requesting to mute the audio amplifier unit in response to at least one of the one of the plurality of signatures not matching the expected signature and the reconstructed volume of the meta data not matching the expected volume.

13. (canceled)

14. (canceled)

15. (canceled)

16. (canceled)

17. (canceled)

18. (canceled)

19. (canceled)

20. (canceled)
